(19) United States
(12) Patent Application Publication
(10) Pub. No.: US 2009/0224768 A1
(43) Pub. Date: Sep. 10, 2009

(54) SHUNT RESISTOR WITH MEASUREMENT CIRCUIT

(76) Inventors: Matthias DOLLANSKY, Schwieberdingen (DE); Roland Hellwig, Asperg (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/401,224

(22) Filed: Mar. 10, 2009

(30) Foreign Application Priority Data
Mar. 10, 2008 (DE) 10 2008 013 408.2

(51) Int. Cl. G01N 27/416; H05K 7/00

(52) U.S. Cl. 324/426; 361/767

(57) ABSTRACT

A shunt resistor with a measurement circuit, retained on the shunt resistor, on a printed circuit board is proposed, in which separate spacers, by way of which the measurement circuit can be put in electrical and mechanical contact with the shunt resistor, are disposed between the printed circuit board of the measurement circuit and the shunt resistor. The printed circuit board of the measurement circuit can be connected in material-locking fashion to the spacers, and the printed circuit board with the spacers can then be mounted by means of material-locking connections on the shunt resistor via the spacers, and the length, position and number of the spacers are dimensioned such that assembly of the printed circuit board with components of predetermined dimensions can be done on the side of the printed circuit board facing toward the shunt resistor.

### CROSS-REFERENCE TO RELATED APPLICATIONS

This application is based on German Patent Application 10 2008 013 408.2 filed Mar. 10, 2008, upon which priority is claimed.

### BACKGROUND OF THE INVENTION

1. Field of the Invention

The invention relates to a shunt resistor having a measurement circuit, in particular for mounting in the load current circuit of a battery for detecting the status of the battery, as a component of an energy management system in motor vehicles.

2. Description of the Prior Art

An increasing number of electrical consumers in motor vehicles leads to a markedly increasing number of field failures, so-called slugs, because of batteries that discharge excessively or are defective. This, along with fuel economies that are often demanded, increasingly requires the use of the energy management system referred at the outset in conjunction with a reliable battery status recognition, which makes the necessary battery information available based on the measurable battery variables of current, voltage, and temperature.

Development work is being done in the direction of an intelligent, compact battery sensor, which detects the battery variables of current, voltage and temperature with high precision and a high scanning rate, and depending on partitioning either partly or entirely takes on the task of battery status recognition. The electrical energy management system is located in a so-called host control unit, which communicates with the battery sensor via a simple, inexpensive mass-produced interface, preferably a so-called LIN bus.

So far, it is usual for the mechanics of the battery sensors to be based on a pole terminal, which has a shunt, a ground cable connection, and integrated electronics. Such an arrangement is know for instance from German Patent Disclosure DE 10 2005 039 587 A1, in which the shunt resistor is clamped directly to a pole terminal, in this case the negative pole, or to a corresponding pole niche in the battery and in practical terms combines the measured distance with the mechanical connection unit.

It is also known, for instance from German Utility Model DE 203 20 473 U1, that a measurement circuit for measuring battery currents in the on-board electrical system of a motor vehicle, for instance, is provided with a shunt resistor that is used for current measurement. Via this shunt resistor, a voltage drop is measured, and then with knowledge of the resistance of the shunt is converted into a current. The electrical and mechanical connection between the measurement circuit on a printed circuit board and the resistor elements is effected, in the known arrangement, by measurement terminals by a four-conductor technique known per se, in which the measurement circuit is constructed as an integrated circuit, or as a so-called ASIC, and the resistor element is constructed for instance as a manganin shunt.

In the known concepts, the measurement circuit is as a rule soldered directly to the shunt resistor, and the resultant slight spacing between the printed circuit board of the measurement circuit and the shunt resistor does not as a rule allow two-sided assembly of the printed circuit board. At least relatively large components are unattainable on the lower side of the printed circuit board.

The electrical and mechanical contact-making is done essentially by means of form-locking connection methods, such as in the arrangement known from DE 203 20 473 U1, by soldering or welding to the measurement circuit; in this prior art, a slight spacing is brought about by measurement terminals, which although they can be lengthened, within limits, cannot be loaded mechanically.

### SUMMARY AND ADVANTAGES OF THE INVENTION

The invention is based on a shunt resistor with a measurement circuit, retained on the shunt resistor, on a printed circuit board, in which according to the invention, advantageously, separate spacers, by way of which the measurement circuit can be put into electrical and mechanical contact with the shunt resistor, are disposed between the printed circuit board of the measurement circuit and the shunt resistor. The printed circuit board of the measurement circuit is provided in material-locking fashion with the spacers, and the printed circuit board with the spacers can then be mounted on the shunt resistor by means of material-locking connections.

It is especially advantageous if the length, position and number of spacers are dimensioned such that assembly of the printed circuit board with components of predetermined dimensions can be performed on the side of the printed circuit board facing toward the shunt resistor.

An advantageous application of the shunt resistor of the invention is obtained upon the detection of the electrical status variables of a battery of a motor vehicle from the load current of the battery; the measurement circuit is connected to the shunt resistor, disposed in the region of a pole terminal of the battery, via the spacers and optionally via further terminal contacts. A connection of the measurement circuit to an energy management system of the motor vehicle can be effected in a manner known per se, for instance via a so-called LIN bus.

The shunt resistor described above can be produced in a simple way such that the material-locking connections of the measurement circuit to the shunt resistor via the spacers are produced by means of a PCB assembly machine using reflow technology, a in a conventional electrical component.

The invention described can be used wherever an electronic measurement circuit is connected to a shunt resistor. A construction and connection technique is advantageously optimized by providing that making the contact between the printed circuit board and the shunt resistor is accomplished, via the spacers of the invention, in such a way that depending on the height or length or also the thickness of the spacers used, electrical components of different sizes can be disposed between the printed circuit board and the shunt resistor. Thus the shunt resistor can easily be assembled on both sides.

### BRIEF DESCRIPTION OF THE DRAWING

The invention 11 be better understood and further objects and advantages thereof will become more apparent from the ensuing detailed description of a preferred embodiment taken in conjunction with the drawing, in which:

FIG. 1 is a schematic side view on a printed circuit board of a measurement circuit, which is electrically connected on a shunt resistor.

### DESCRIPTION OF THE PREFERRED EMBODIMENT

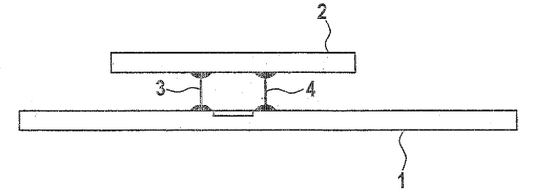

In FIG. 1, a shunt resistor 1 is shown, which is for instance equivalent to the shunt resistors known from the prior art cited at the outset. The shunt resistor 1, for example comprising manganin, can thus be a resistor element with two lateral connection elements for insertion into a current circuit, not described in further detail here, of a battery for a motor vehicle. The status of the battery can be learned by measuring electrical variables, in particular the load current downstream of the pole terminals of the battery, using a measurement circuit which is disposed on a printed circuit board 2.

The printed circuit board 2 is provided in material-locking fashion, preferably by soldering. Likewise two spacers 3 and 4, in turn are mounted in material-locking fashion on the shunt resistor 1, here again preferably by soldering. By means of the height or length, the position and the number of the spacers 3 and 4, two-sided assembly of the printed circuit board 2 with components can be accomplished, since in this case the spacing between the shunt resistor and the printed circuit board can then be selected to be sufficient so that components, not shown here, can also be disposed on the side of the printed circuit board 2 facing toward the shunt resistor 1. The measurement circuit on the printed circuit board 2 can be connected to an energy management system of the motor vehicle via a so-called LIN bus.

The foregoing relates to a preferred exemplary embodiment of the invention, it being understood that other variants and embodiments thereof are possible within the spirit and scope of the invention, the latter being defined by the appended claims.

We claim:

1. A shunt resistor having a measurement circuit, retained on the shunt resistor by means of a printed circuit board, at least two spacers provided, by way of which the measurement circuit can be put in electrical and mechanical contact with the shunt resistor, wherein the spacers are disposed between the printed circuit board of the measurement circuit and the shunt resistor.

2. The shunt resistor as defined by claim 1, wherein the printed circuit board of the measurement circuit is provided with the spacers in material-locking fashion, and the printed circuit board with the spacers can be mounted on the shunt resistor by means of material-locking, connections.

3. The shunt resistor as defined by claim 1, wherein length, position and number of spacers are dimensioned such that assembly the printed circuit board with components of predetermined dimensions can be performed on a side of the printed circuit board facing toward the shunt resistor.

4. The shunt resistor as defined by claim 2, wherein length, position and number of spacers are dimensioned such that assembly the printed circuit board with components of predetermined dimensions can be performed on a side of the printed circuit board facing toward the shunt resistor.

5. The shunt resistor as defined by claim 1, wherein for detecting electrical status variables of a battery of a motor vehicle from a load current of the battery, the measurement circuit is connected to the shunt resistor, disposed in a region of a pole terminal of the battery, via the spacers and optionally via further terminal contacts; and wherein a connection of the measurement circuit to an energy management system of the motor vehicle is effected via a LIN bus.

6. The shunt resistor as defined by claim 2, wherein for detecting electrical status variables of a battery of a motor vehicle from a load current of the battery, the measurement circuit is connected to the shunt resistor, disposed in a region of a pole terminal of the battery, via the spacers and optionally via further terminal contacts; and wherein a connection of the measurement circuit to an energy management system of the motor vehicle is effected via a LIN bus.

7. The shunt resistor as defined by claim 3, wherein for detecting electrical status variables of a battery of a motor vehicle from a load current of the battery, the measurement circuit is connected to the shunt resistor, disposed in a region of a pole terminal of the battery, via the spacers and optionally via further terminal contacts; and wherein a connection of the measurement circuit to an energy management system of the motor vehicle is effected via a LIN bus.

8. The shunt resistor as defined by claim 4, wherein for detecting electrical status variables of a battery of a motor vehicle from a load current of the battery, the measurement circuit is connected to the shunt resistor, disposed in a region of a pole terminal of the battery, via the spacers and optionally via further terminal contacts; and wherein a connection of the measurement circuit to an energy management system of the motor vehicle is effected via a LIN bus.

9. The shunt resistor as defined by claim 2, wherein the material-locking connections of the measurement circuit to the shunt resistor via the spacers are produced by means of a PCB assembly machine using reflow technology.

10. The shunt resistor as defined by claim 4, wherein the material-locking connections of the measurement circuit to the shunt resistor via the spacers are produced by means of a PCB assembly machine using reflow technology.

11. The shunt resistor as defined by claim 6, wherein the material-locking connections of the measurement circuit to the shunt resistor via the spacers are produced by means of a PCB assembly machine using reflow technology.

12. The shunt resistor as defined by claim 8, wherein the material-locking connections of the measurement circuit to the shunt resistor via the spacers are produced by means of a PCB assembly machine using reflow technology.
